(19) United States
(12) Patent Application Publication
(10) Pub. No.: US 2023/0320068 A1
(43) Pub. Date: Oct. 5, 2023

(54) SEMICONDUCTOR DEVICE AND METHOD FOR FABRICATING THE SAME

(71) Applicant: SK hynix Inc., Gyeonggi-do (KR)

(72) Inventor: Seung Hwan KIM, Gyeonggi-do (KR)

(21) Appl. No.: 17/988,904

(22) Filed: Nov. 17, 2022

(30) Foreign Application Priority Data
Mar. 29, 2022 (KR) 10-2022-0038978

(51) Int. Cl. H01L 27/108

(52) U.S. Cl. CPC H01L 27/10805; H01L 27/10873; H01L 27/10885

(57) ABSTRACT

A semiconductor device includes a lower structure; a plurality of active layers horizontally oriented along a direction parallel to a surface of the lower structure; a plurality of bit lines coupled to the active layers, respectively, and extended in a vertical direction to the surface of the lower structure; a word line horizontally extended in a direction crossing the active layers over the active layers; and a capping layer disposed between the bit lines and the word line, the capping layer including an air gap disposed between the bit lines and the word lines.

### CROSS-REFERENCE TO RELATED APPLICATIONS

The present application claims priority to Korean Patent Application No. 10-2022-0038978, filed on Mar. 29, 2022, which is incorporated herein by reference in its entirety.

### BACKGROUND

### Field

The present invention relates to a semiconductor device, and more particularly, to a semiconductor device having a three-dimensional structure and a method for fabricating the same.

### Description of the Related Art

In order to increase the net die of a memory device, the size of a memory cell has been continuously reduced. As the size of the memory cell is miniaturized, it is necessary to reduce the parasitic capacitance (Cb) and increase the capacitance. However, it is difficult to increase the net die yield due to the structural limitation of the memory cell.

Recently, three-dimensional semiconductor devices including memory cells arranged three-dimensionally have been considered.

### SUMMARY

Embodiments of the present invention provide a semiconductor device having a highly integrated memory cell and a method of fabricating the same.

According to one embodiment of the present invention, a semiconductor device may include: a lower structure; a plurality of active layers horizontally oriented along a direction parallel to a surface of the lower structure; a plurality of bit lines coupled to the active layers, respectively, and extended in a vertical direction to the surface of the lower structure; a word line horizontally extended in a direction crossing the active layers over the active layers; and a capping layer disposed between the bit lines and the word line, the capping layer including an air gap disposed between the bit lines and the word lines.

According to another embodiment of the present invention, a semiconductor device may include: a lower structure; a plurality of active layers horizontally spaced apart along a direction parallel to a surface of the lower structure; a word line horizontally extended in a direction crossing the active layers over the active layers; a plurality of bit lines coupled one side of the active layers, respectively, and extended in a vertical direction to the surface of the lower structure; a plurality of capacitors coupled to another side of the active layers, respectively; a bit line-side capping layer disposed between the bit lines and the word line, disposed on a sidewall of the word line, and including an air gap; and a capacitor-side capping layer disposed between the capacitors and the word line and disposed on another sidewall of the word line.

According to still another embodiment of the present invention, a method of fabricating a semiconductor device may include: forming a stack body in which a first dielectric layer, a first sacrificial layer, a semiconductor layer, a second sacrificial layer, and a second dielectric layer are sequentially stacked over the lower structure; forming an opening by etching the stack body; replacing portions of the first and second sacrificial layers exposed by the opening with word lines; forming a capping layer on a sidewall of the word lines, the capping layer including an inner liner and an outer liner on a sidewall of the word lines, and a sacrificial material bounded by the inner and outer liners; replacing the sacrificial material with an air gap; and forming a bit line filling the opening. The sacrificial material includes a decomposable material. The sacrificial material includes a carbon-containing material. The sacrificial material includes amorphous carbon. At least one of the inner liner and the outer liner includes silicon oxide. The replacing of the sacrificial material with the air gap includes a plasma treatment. The air gap is extended along a sidewall of the word lines. The forming of the capping layer includes: forming an inner liner layer on a sidewall of the word lines; forming a sacrificial liner layer over the inner liner layer; forming a gap-fill layer filling the opening over the sacrificial liner layer; forming a vertical opening by etching the gap-fill layer; forming the inner liner and a sacrificial liner by etching the inner liner layer and the sacrificial liner layer; forming a sacrificial recess by removing the sacrificial liner; forming the sacrificial material filling the sacrificial recess; and forming the outer liner over the sacrificial material. The word line includes a double word line structure or a single word line structure. The air gap includes an isolated structure disposed to correspond to each of the bit lines, respectively.

According to yet another embodiment of the present invention, a semiconductor device may include: a lower structure; a plurality of active layers horizontally oriented along a direction parallel to a surface of the lower structure; a plurality of bit lines coupled one side of the active layers, respectively, and extended in a vertical direction to the surface of the lower structure; a word line horizontally extended in a direction crossing the active layers over the active layers; and a capping layer disposed between the bit lines and the word line, disposed on a sidewall of the word line, and including an isolated air gap.

Since the present technology forms an air gap between the word line and the bit line, it is possible to reduce parasitic capacitance.

### BRIEF DESCRIPTION OF THE DRAWINGS

FIG. 1 is a schematic plan view of a semiconductor device according to one embodiment of the present invention.

FIG. 2A is a cross-sectional view taken along line A-A′ of FIG. 1.

FIG. 28 is a detailed view of the bit line-side capping layer of FIG. 2A.

FIGS. 3 to 13 are diagrams illustrating a method of fabricating a semiconductor device according to another embodiment of the present invention.

FIG. 14 is a schematic cross-sectional view of a semiconductor device according to another embodiment of the present invention.

FIG. 15 is a schematic plan view of a semiconductor device according to another embodiment of the present invention.

### DETAILED DESCRIPTION

Embodiments described herein will be described with reference to cross-sectional, plan and block diagrams, which are ideal schematic diagrams of the present invention. Accordingly, the shapes shown in the illustrative drawings may be modified due to fabricating technology and/or tolerance. Accordingly, the embodiments of the present invention are not limited to the specific shapes shown, but also include changes in the shapes caused by the fabricating process. Accordingly, the regions illustrated in the drawings have schematic properties, and the shapes of the regions illustrated in the drawings are intended to illustrate specific shapes of regions of the device, and not to limit the scope of the invention.

In embodiments to be described later, memory cells are vertically stacked to increase memory cell density and reduce parasitic capacitance.

In the following embodiments, an air gap may be formed between a word line and a bit line in order to reduce a bit line total capacitance in a three-dimensional (3D) dynamic random-access memory (DRAM).

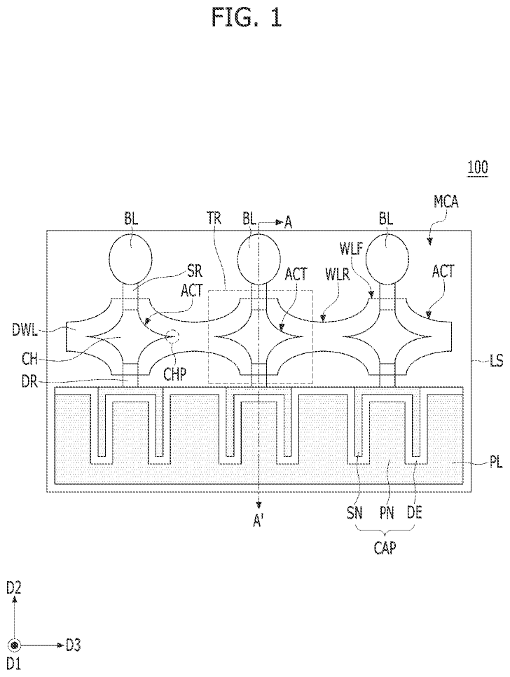

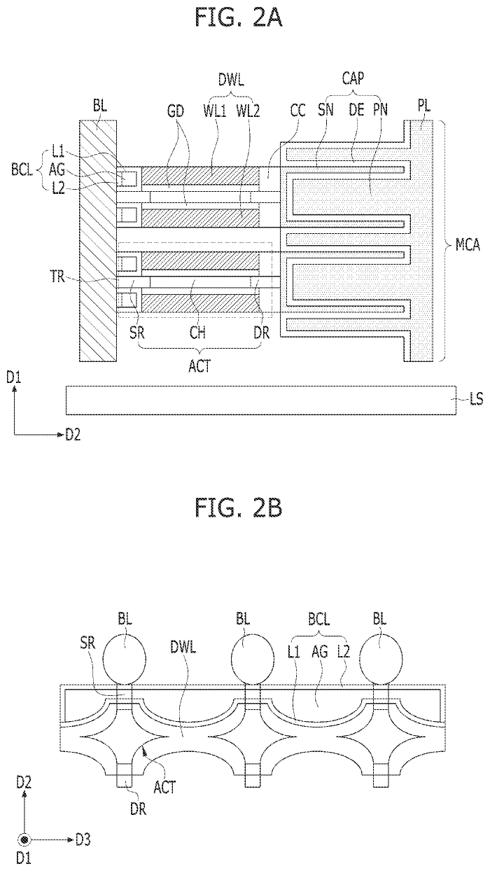

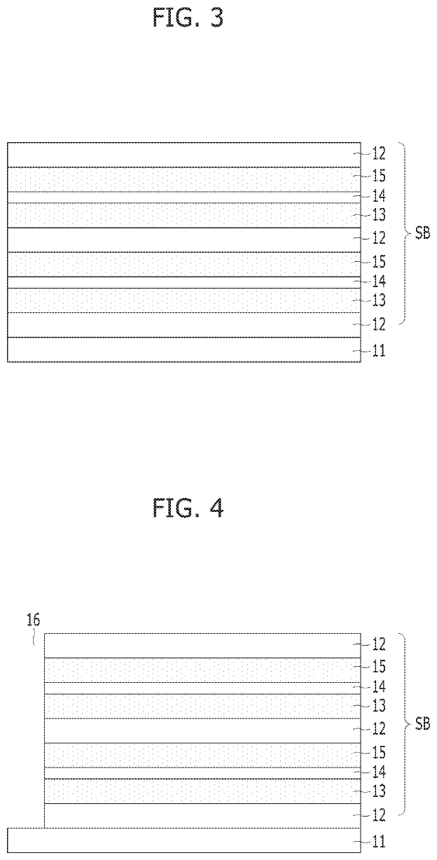

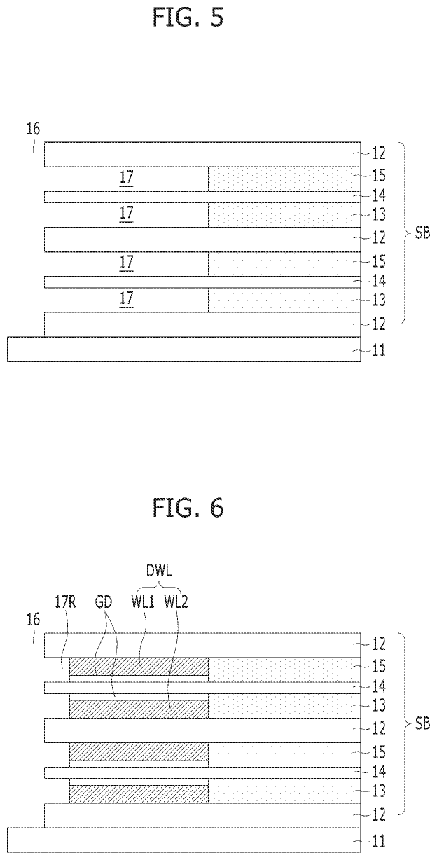

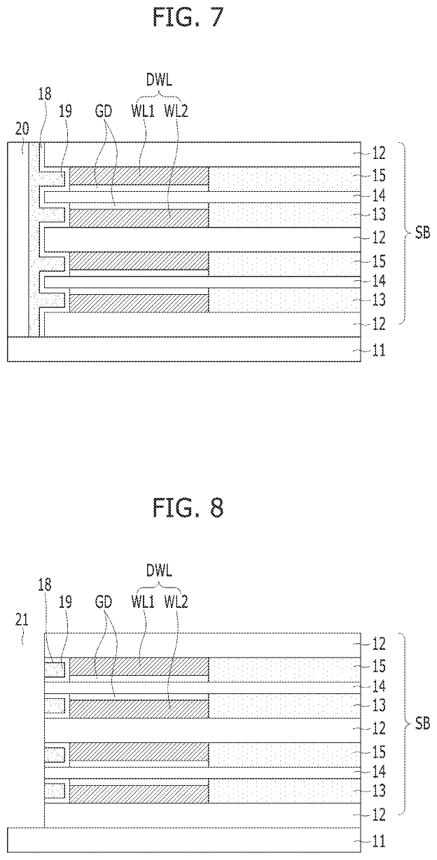

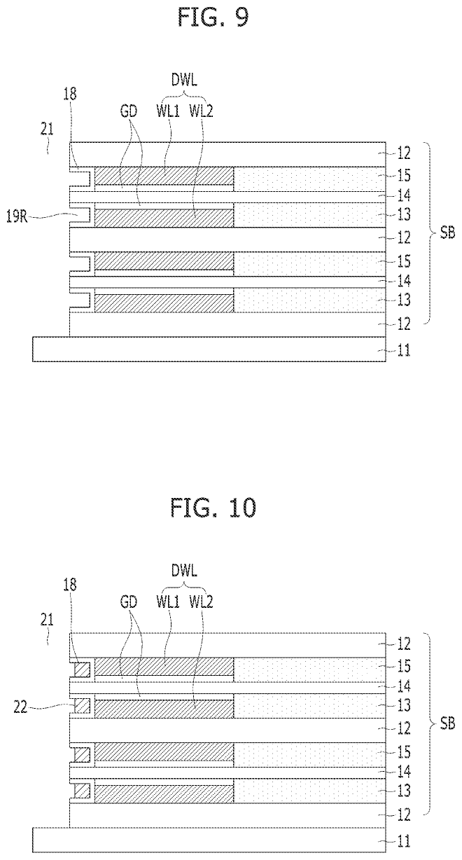

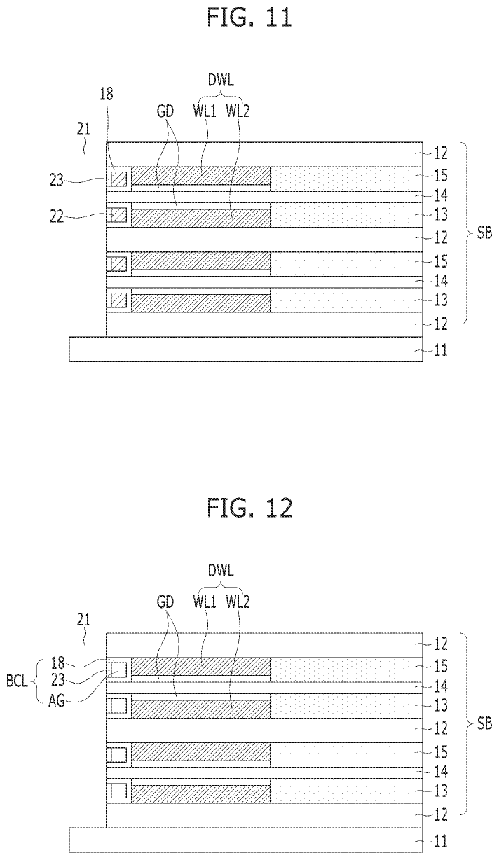

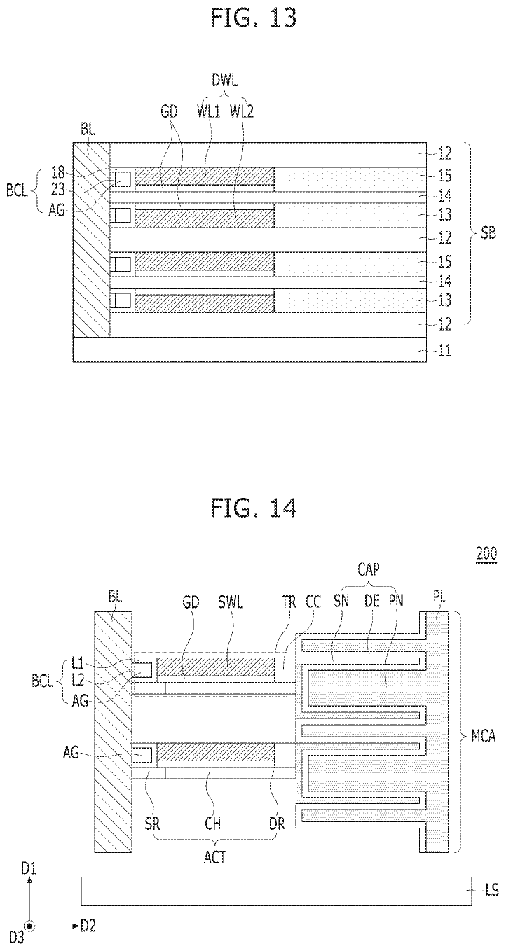

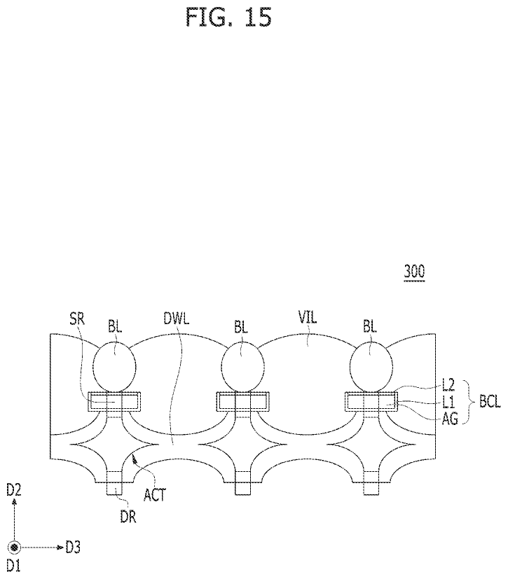

FIG. 1 is a schematic plan view of a semiconductor device according to one embodiment of the present invention. FIG. 2A is a cross-sectional view taken along line A-A′ of FIG. 1. FIG. 2B is a detailed view of the bit line-side capping layer of FIG. 2A.

Referring to FIGS. 1 to 2B, the semiconductor device 100 may include a lower structure LS and a memory cell array MCA. The memory cell array MCA may be disposed on the lower structure LS.

The memory cell array MCA may be a three-dimensional array of a plurality of memory cells. The memory cell array MCA may include a plurality of vertical conductive lines BL, a plurality of horizontal conductive lines DWL, a plurality of switching elements TR, and a plurality of data storage elements CAP. One switching element TR may be disposed between one horizontal conductive line DWL and one vertical conductive line BL, The vertical conductive lines BL may be abbreviated as bit lines BL, and the horizontal conductive lines DWL may be abbreviated as word lines DWL or gate electrodes. The switching elements TR may be abbreviated as a transistor TR, and the data storage elements CAP may be abbreviated as a capacitor CAP.

A single transistor TR may include one active layer ACT and one word line DWL, and the word line DWL may have a double word line structure. For example, as shown in FIG. 2A, the double word line structure may include first and second word lines WL1 and WL2 facing each other with the active layer ACT interposed therebetween. The first word line WL1 may include a first gate electrode, and the second word line WL2 may include a second gate electrode. The first word line WL1 may be disposed above the active layer ACT, and the second word line WL2 may be disposed below the active layer ACT. The active layer ACT may include a horizontal conductive layer, A single capacitor CAP may include a storage node SN, a dielectric layer DE, and a plate node PN.

The bit line BL may extend vertically in the first direction D1, The active layer ACT may extend along a second direction D2 crossing the first direction D1. The active layer ACT may be horizontally oriented along the second direction D2 parallel to the surface of the lower structure LS. The word line DWL may extend along a third direction D3 crossing the first and second directions D1 and D2. The plate nodes PN of the capacitors CAP stacked along the first direction D1 may be interconnected to be coupled to the plate line PL.

The bit line BL may be vertically oriented along the first direction D1 which is perpendicular to the surface of the lower structure LS. The bit line BL may be referred to as a ‘vertically oriented bit line’ or a ‘pillar bit line’. The bit line BL may include a conductive material. The bit line BL may include a silicon-based material, a metal-based material, or a combination thereof. The bit line BL may include silicon, metal, metal nitride, metal silicide, or a combination thereof. The bit line BL may include polysilicon, titanium nitride, tungsten, or a combination thereof. For example, the bit line BL may include polysilicon or titanium nitride (TiN) doped with N-type impurities. The bit line BL may include a TiN/W stack, and the TiN/W stack may have a structure including titanium nitride and tungsten on the titanium nitride.

The word line DWL may extend along the third direction D3, and the active layer ACT may extend along the second direction D2. The active layer ACT may be horizontally arranged along the second direction D2 from the bit line BL. The word line DWL may include a pair of word lines, that is, a first word line WL1 and a second word line WL2. The first word line WL1 and the second word line WL2 may face (or overlap) each other along the first direction D1 with the active layer ACT interposed therebetween. A gate dielectric layer GD may be formed on the upper and lower surfaces of the active layer ACT. The gate dielectric layer GD may be disposed between the active layer ACT and the first word line WL1, and may also be disposed between the active layer ACT and the second word line WL2.

The transistor TR may be a cell transistor and may have one word line DWL having a double word line structure. In the word line DWL, the first word line WL1 and the second word line WL2 may have the same potential. For example, the first word line WL1 and the second word line WL2 may form a pair, and the same word line driving voltage may be applied to the first word line WL1 and the second word line WL2, As described above, the semiconductor device 100 according to one embodiment of the present invention may include a double word line structure in which two of the first and second word lines WL1 and WL2 are adjacent to one active layer ACT.

In another embodiment, the first word line WL1 and the second word line WL2 may have different potentials. For example, a word line driving voltage may be applied to the first word line WL1, and a ground voltage may be applied to the second word line WL2. The second word line WL2 may be referred to as a back word line or a shield word line. In another embodiment, a ground voltage may be applied to the first word line WL1, and a word line driving voltage may be applied to the second word line WL2.

The active layer ACT may include a semiconductor material. The active layer ACT may include a silicon-containing layer or a silicon germanium-containing layer. For example, the active layer ACT may include silicon, monocrystalline silicon, polysilicon, doped polysilicon, undoped polysilicon, amorphous silicon, silicon germanium, or a combination thereof. In another embodiment, the active layer ACT may include a nano-wire or a nano sheet, and the nano-wire and the nano sheet may be formed of a semiconductor material. The active layer ACT may include a channel CH, a first source/drain region SR, and a second source/drain region DR. The first source/drain region SR and the second source/drain region DR may be formed in the active layer ACT by ion implantation or plasma doping of impurities. The channel CH may vertically overlap the first and second word lines WL1 and WL2. The channel CH may include channel protrusions CHP (as shown in FIG. 1) that are symmetrical to each other in the third direction D3. The channel protrusions CHP may vertically overlap the first and second word lines WL1 and WL2.

Each of the first and second word lines WL1 and WL2 may include notch-type sidewalls facing each other. An individual notch-type sidewall may include flat surfaces WLF and recessed surfaces WLR. The flat surfaces WLF and the recessed surfaces WLR may be alternately repeated along the third direction D3. The flat surfaces WLF may be flat sidewalls, and the recessed surfaces WLR may be recessed sidewalls. The flat surfaces WLF may vertically overlap the first and second source/drain regions SR and DR. The recessed surfaces WLR may not overlap the first and second source/drain regions SR and DR. In the second direction D2, the flat surfaces WLF may face each other. In the second direction D2, the recessed surfaces WLR may face each other.

In another embodiment, the active layer ACT may include an oxide semiconductor material. The oxide semiconductor material may include indium gallium zinc oxide (IGZO).

The active layer ACT may have a thickness smaller than that of either of the first and second word lines WL1 and WL2. In other words, a vertical thickness of the active layer ACT in the first direction D1 may be thinner than a vertical thickness of either of the first and second word lines WL1 and WL2 in the first direction D1, As such, the thin active layer ACT may be referred to as a thin-body active layer.

The gate dielectric layer GD may include silicon oxide, silicon nitride, metal oxide, metal oxynitride, metal silicate, high-k material, ferroelectric material, antiferroelectric material or a combination thereof. The gate dielectric layer GD may include SiO₂, Si₃N₄, HfO₂, Al₂O₃, ZrO₂, AlON, HfON, HfSiO, HfSiON, HfZrO, or a combination thereof.

The word line DWL may include a conductive material. The first and second word lines WL1 and WL2 may include a metal, a metal mixture, a metal alloy, or a semiconductor material. The first and second word lines WL1 and WL2 may include titanium nitride, tungsten, polysilicon, or a combination thereof. For example, the first and second word lines WL1 and WL2 may include a TiN/W stack in which titanium nitride and tungsten are sequentially stacked. The first and second word lines WL1 and WL2 may include an N-type workfunction material or a P-type workfunction material. The N-type workfunction material may have a low workfunction of 4.5 eV or less, and the P-type workfunction material may have a high workfunction of 4.5 eV or more.

The capacitor CAP may be horizontally disposed along the second direction D2 from the transistor TR, The capacitor CAP may include the storage node SN horizontally extending from the active layer ACT in the second direction D2, The capacitor CAP may further include a dielectric layer DE and a plate node PN on the storage node SN. The storage node SN, the dielectric layer DE, and the plate node PN may be horizontally arranged in the second direction D2. The storage node SN may have a horizontally oriented cylinder-shape. The dielectric layer DE may conformally cover the cylinder inner wall and the cylinder outer wall of the storage node SN, The plate node PN may cover a cylindrical inner wall and a cylindrical outer wall of the storage node SN on the dielectric layer DE. The plate nodes PN may be coupled to the plate line PL. The storage node SN may be electrically coupled to the second source/drain region DR of the active layer ACT. The bit line BL may be electrically coupled to the first source/drain region SR of the active layer ACT.

The storage node SN may have a three-dimensional structure, and the storage node SN of the three-dimensional structure may have a horizontal three-dimensional structure oriented along the second direction D2. As an example of the three-dimensional structure, the storage node SN may have a cylindrical shape. In another embodiment, the storage node SN may have a pillar shape or a pylinder shape. The pylinder shape may refer to a structure in which a pillar shape and a cylindrical shape are merged.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), titanium nitride/tungsten (TiN/W) stack, and tungsten nitride/tungsten (WN/W) stack. The plate node PN may include a combination of a metal-based material and a silicon-based material. For example, the plate node PN may be a stack of titanium nitride/silicon germanium/tungsten nitride (TiN/SiGe/WN), In the titanium nitride/silicon germanium/tungsten nitride (TiN/SiGe/WN) stack, silicon germanium may be a gap-fill material filling the inside of the cylinder of the storage node SN on the titanium nitride, titanium nitride (TiN) may serve as plate node PN of a capacitor CAP, and tungsten nitride may be a low-resistance material.

The dielectric layer DE may be referred to as a capacitor dielectric layer. The dielectric layer DE may include silicon oxide, silicon nitride, a high-k material, or a combination thereof. A high-k material may have a higher dielectric constant than silicon oxide. Silicon oxide (SiO₂) may have a dielectric constant of about 3.9, and the dielectric layer DE may include a high-k material having a dielectric constant of 4 or more. A high-k material may have a dielectric constant of about 20 or more. A high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the dielectric layer DE may be formed of a composite layer including two or more layers of the aforementioned high-k materials.

The dielectric layer DE may be formed of zirconium-based oxide. The dielectric layer DE may have a stack structure including at least zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. In another embodiment, the dielectric layer DE may be formed of hafnium (Hf)-based oxide. The dielectric layer DE may have a stack structure including at least hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater band gap energy (hereinafter abbreviated as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a bandgap greater than that of the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. In another embodiment, the dielectric layer DE may include a laminated structure in which a high-k material and a high-bandgap material are alternately stacked. For example, ZAZA (ZrO₂/Al₂O₃/ZrO₂/Al₂O₃) stack, ZAZAZ (ZrO₂/Al₂O₃/ZrO₂/Al₂O₃/ZrO₂) stack, HAHA (HfO₂/Al₂O₃/HfO₂/Al₂O₃) stack, or HAHAH (HfO₂/Al₂O₃/HfO₂/Al₂O₃/HfO₂) stack may be included. In the above laminate structure, aluminum oxide (Al₂O₃) may be thinner than zirconium oxide (ZrO₂) and hafnium oxide (HfO₂).

In another embodiment, the dielectric layer DE may include a stack structure, a laminate structure, or a mutual mixing structure including zirconium oxide, hafnium oxide, and aluminum oxide.

In another embodiment, the dielectric layer DE may include a ferroelectric material or an antiferroelectric material.

In another embodiment, an interface control layer for improving leakage current may be further formed between the storage node SN and the dielectric layer DE. The interface control layer may include titanium oxide (TiO₂), niobium oxide, or niobium nitride. The interface control layer may also be formed between the plate node PN and the dielectric layer DE.

The capacitor CAP may include a metal-insulator-metal (MIM) capacitor. The storage node SN and the plate node PN may include a metal-based material.

The capacitor CAP may be replaced with another data storage material. For example, the data storage material may be a phase change material, a magnetic tunnel junction (MTJ), or a variable resistor material.

Active layers ACT adjacent to each other along the first direction D1 may contact one bit line BL. The active layers ACT adjacent to each other along the third direction D3 may share one word line DWL. The capacitors CAP may be coupled to each of the active layers ACT. The capacitors CAP may share one plate line PL. An individual active layer ACT may be thinner than either of the first and second word lines WL1 and WL2 of the word line DWL.

In the memory cell array MCA, a plurality of word lines DWL may be vertically stacked in the first direction D1 (as shown in FIG. 2A). The individual word line DWL may include a pair of a first word line WL1 and a second word line WL2, Between the first word line WL1 and the second word line WL2, a plurality of active layers ACT may be spaced apart from each other in the third direction D3 and arranged horizontally.

A capacitor-side capping layer CC may be formed between the capacitor CAP and the word line DWL. The capacitor-side capping layer CC may include silicon oxide, silicon carbon oxide, silicon nitride, or a combination thereof. The capacitor-side capping layer CC may not include an air gap. The capacitor-side capping layer CC may include an air gap-free material.

The lower structure LS may be a material suitable for semiconductor processing. The lower structure LS may include at least one of a conductive material, a dielectric material, and a semiconductor material. The lower structure LS may include a semiconductor substrate, and the semiconductor substrate may be formed of a material containing silicon. The lower structure LS may include silicon, monocrystalline silicon, polysilicon, amorphous silicon, silicon germanium, monocrystalline silicon germanium, polycrystalline silicon germanium, carbon doped silicon, a combination thereof, or a multilayer thereof. The lower structure LS may include other semiconductor materials such as germanium. The lower structure LS may include a III/V group semiconductor substrate, for example, a compound semiconductor substrate such as GaAs. The lower structure LS may include a silicon on insulator (SOI) substrate.

In another embodiment, the lower structure LS may include peripheral circuits. The peripheral circuits may include a plurality of peripheral circuit transistors. The peripheral circuits may be disposed at a lower level than the memory cell array MCA. This may be referred to as a COP (Cell over PERI) structure. The peripheral circuits may include at least one control circuit for driving the memory cell array MCA. The at least one control circuit of the peripheral circuits may include an N-channel transistor, a P-channel transistor, a CMOS circuit, or a combination thereof. At least one control circuit of the peripheral circuits may include an address decoder circuit, a read circuit, a write circuit, and the like. At least one control circuit of the peripheral circuits may include a planar channel transistor, a recess channel transistor, a buried gate transistor, a fin channel transistor (FinFET), and the like.

For example, the peripheral circuits may include sub word line drivers and a sense amplifier. The word line DWL may be coupled to sub word line drivers. The bit lines BL may be coupled to the sense amplifier.

Referring back to FIGS. 2A and 2B, a bit line-side capping layer BCL may be formed between the bit line BL and the word line DWL. The bit line-side capping layer BCL may include an air gap AG, A bit line-side capping layer BCL having an air gap AG embedded therein may be disposed between the first word line WL1 and the bit line BL, and between the second word line WL2 and the bit line BL, a bit line-side capping layer BCL having an air gap AG embedded therebetween may be disposed. The bit line-side capping layers BCL may vertically overlap the first source/drain region SR.

The air gap AG may be disposed between the bit line BL and the word line DWL. The air gap AG may be disposed above and below the active layer ACT, respectively. The air gap AG may be disposed above and below the first source/drain region SR, respectively. The air gap AG may be parallel to the active layer ACT and the first source/drain region SR. The air gap AG may have a larger critical dimension than the active layer ACT or the first source/drain region SR. For example, the width of the air gap AG in the third direction D3 may be greater than the width of the first source/drain region SR in the third direction D3.

The bit line-side capping layer BCL may further include an inner liner L1 and an outer liner L2, and the air gap AG may be closed (or bounded at least partially) by the inner liner L1 and the outer liner L2. That is, the air gap AG may be an embedded air gap disposed between the inner liner L1 and the outer liner L2, Referring back to FIG. 2B, the air gap AG may extend along the third direction D3 and may extend along one sidewall of the word line DWL.

The inner liner L1 and the outer liner L2 of the bit line-side capping layer BCL may include silicon oxide, silicon carbon oxide, silicon nitride, or a combination thereof.

Referring to FIGS. 1 to 2B, since the air gap AG is formed between the word line DWL and the bit line BL, it is possible to reduce the parasitic capacitance between the word line DWL and the bit line BL, thereby reducing the sensing margin.

In another embodiment, the capacitor-side capping layer CC may also include an embedded air gap in the same manner as the bit line-side capping layer BCL.

As shown in FIGS. 3 to 13 are diagrams illustrating a method of fabricating a semiconductor device according to an embodiment of the present invention.

As shown in FIG. 3, a stack body SB may be formed on the lower structure 11. The stack body SB may be formed by repeatedly forming a sub-stack stacked in the order of the dielectric layer 12, the first sacrificial layer 13, the semiconductor layer 14, and the second sacrificial layer 15, The dielectric layer 12 may be silicon oxide, and the first and second sacrificial layers 13 and 15 may be silicon nitride. The semiconductor layer 14 may include a silicon layer, a monocrystalline silicon layer, or a polysilicon layer. The uppermost layer in the stack body SB may be the dielectric layer 12. In another embodiment, the semiconductor layer 14 may include an oxide semiconductor material. The dielectric layer 12 under the first sacrificial layer 13 may be referred to as a first dielectric layer, and the dielectric layer 12 above the second sacrificial layer 15 may be referred to as a second dielectric layer.

As shown in FIG. 4, a first opening 16 passing through a portion of the stack body SB may be formed. The first opening 16 may extend vertically from the lower structure 11. The first opening 16 may be a hole-type opening.

As shown in FIG. 5, the first sacrificial layer 13 and second sacrificial layer 15 may be recessed through the first opening 16, Accordingly, horizontal recesses 17 may be formed between the dielectric layer 12 and the semiconductor layer14. A portion of the semiconductor layer 14 may be exposed by the horizontal recesses 17.

As shown in FIG. 6, a gate dielectric layer GD may be formed on the exposed semiconductor layers 14. The gate dielectric layer GD may be formed by an oxidation process or a deposition process. The gate dielectric layer GD may include silicon oxide, silicon nitride, a high-k layer, or a combination thereof.

Next, a first word line WL1 and a second word line WL2 partially filling the horizontal recesses 17 may be formed on the gate dielectric layer GD. The first and second word lines WL1 and WL2 may constitute one word line DWL. Residual horizontal recesses 17R may be defined after the word line DWL is formed.

As shown in FIG. 7, an inner liner layer 18 and a sacrificial liner layer 19 may be sequentially formed on the residual horizontal recesses 17R. The inner liner layer 18 may include silicon oxide, and the sacrificial liner layer 19 may include silicon nitride.

A sacrificial gap-fill layer 20 filling the first opening 16 may be formed on the sacrificial liner layer 19, The sacrificial gap-fill layer 20 may include silicon oxide.

As shown in FIG. 8, after the sacrificial gap-fill layer 20 is etched, a portion of the sacrificial liner layer 19 and the inner liner layer 18 may be etched to form the second opening 21, The second opening 21 may have the same shape as the first opening 16. The second opening 21 may be referred to as a vertical opening.

After forming the second opening 21, the inner liner 18 and the sacrificial liner layer 19 may remain on the sidewall of the word line DWL.

As shown in FIG. 9, the sacrificial liner layer 19 may be selectively removed. Accordingly, the sacrificial recess 19R may be formed in the space where the sacrificial liner layer 19 is removed.

As shown in FIG. 10, a sacrificial material 22 may be formed to fill the sacrificial recess 19R. The sacrificial material 22 may include a decomposable material. The sacrificial material 22 may include a carbon-containing material. The sacrificial material 22 may include amorphous carbon.

As shown in FIG. 11, an outer liner 23 may be formed on the sacrificial material 22. The outer liner 23 may include silicon oxide. The outer liner 23 may be formed by deposition and etching of silicon oxide.

As shown in FIG. 12, a plasma treatment may be performed to form the air gap AG, The sacrificial material 22 may be decomposed and volatilized by plasma treatment. The air gap AG may be formed by volatilization of the sacrificial material 22.

In this way, the sacrificial material 22 may be replaced with the air gap AG by plasma processing. The air gap AG may be closed (or bounded at least partially) by an inner liner 18 and an outer liner 23, The combination of the inner liner 18, the air gap AG and the outer liner 23 may constitute the bit line-side capping layer BCL.

As shown in FIG. 13, a bit line BL filling the second opening 21 may be formed.

FIG. 14 is a schematic cross-sectional view of a semiconductor device according to another embodiment of the present invention. The semiconductor device 200 of FIG. 14 may be similar to the semiconductor device 100 of FIGS. 1 to 2B. Hereinafter, detailed descriptions of some of the duplicative components will be described with reference to FIGS. 1 to 2B.

Referring to FIGS. 1, 2A, 2B, and 14, the semiconductor device 200 may include a lower structure LS and a memory cell array MCA. The memory cell array MCA may be disposed on the lower structure LS.

The memory cell array MCA may be a three-dimensional array of a plurality of memory cells. The memory cell array MCA may include a plurality of bit lines BL, a plurality of transistors TR, and a plurality of capacitors CAP. An individual transistor TR may include one active layer ACT and one single word line SWL, and the single word line SWL may refer to a structure including one word line. The active layer ACT may include a first source/drain region SR, a channel CH, and a second source/drain region DR. The capacitor CAP may include a storage node SN, a dielectric layer DE, and a plate node PN. The plate nodes PN of the capacitors CAP stacked in the first direction D1 may be coupled to the plate line PL.

A bit line-side capping layer BCL may be formed between the bit line BL and the single word line SWL. The bit line-side capping layer BCL may include an inner liner L1, an outer liner L2, and an air gap AG. The inner liner L1 and the outer liner L2 of the bit line-side capping layer BCL may include a dielectric material. For example, the inner liner L1 and the outer liner L2 may include silicon oxide, silicon carbon oxide, silicon nitride, or a combination thereof. The air gap AG may be sealed by the inner liner L1 and the outer liner L2, That is, the air gap AG may be an embedded air gap. The air gap AG may extend along the third direction D3 and may extend along one sidewall of the single word line SWL.

Referring to FIG. 14, since the air gap AG is formed between the single word line DWL and the bit line BL, it is possible to reduce the parasitic capacitance between the single word line SWL and the bit line BL, Accordingly, a sensing margin may be reduced.

In another embodiment, the single word line SWL may be replaced with a gate all around word line surrounding the active layers ACT adjacent in the third direction D3.

FIG. 15 is a schematic plan view of a semiconductor device according to another embodiment of the present invention. The semiconductor device of FIG. 15 may be similar to the semiconductor device 100 of FIGS. 1 to 2B. Hereinafter, detailed descriptions of duplicative components will be omitted.

Referring to FIGS. 1, 2A, 2B, and 15, the semiconductor device 300 may include a lower structure LS and a memory cell array MCA. The memory cell array MCA may be disposed on the lower structure LS. The memory cell array MCA may be a three-dimensional array of a plurality of memory cells. The memory cell array MCA may include a plurality of bit lines BL, a plurality of word lines DWL, a plurality of transistors TR, and a plurality of capacitors CAP. One transistor TR may be disposed between one word line DWL and one bit line BL.

The individual transistor TR may include one active layer ACT and one word line DWL, and the word line DWL may have a double word line structure. For example, the double word line structure may include first and second word lines WL1 and WL2 facing each other with the active layer ACT interposed therebetween. The individual capacitor CAP may include a storage node SN, a dielectric layer DE, and a plate node PN.

The active layer ACT may include a channel CH, a first source/drain region SR, and a second source/drain region DR. The channel CH may include channel protrusions CHP that are symmetrical to each other in the third direction D3.

The bit line BL may extend vertically in the first direction D1, The active layer ACT may extend along a second direction D2 crossing the first direction D1. The active layer ACT may be horizontally oriented along the second direction D2 parallel to the surface of the lower structure LS. The word line DWL may extend along a third direction D3 crossing the first and second directions D1 and D2. The plate nodes PN of the capacitors CAP stacked along the first direction D1 may be interconnected to be coupled to the plate line PL.

A capacitor-side capping layer CC may be formed between the capacitor CAP and the word line DWL. The capacitor-side capping layer CC may include silicon oxide, silicon carbon oxide, silicon nitride, or a combination thereof. The capacitor-side capping layer CC may not include an air gap. The capacitor-side capping layer CC may include an air gap-free material.

A bit line-side capping layer BCL may be formed between the bit line BL and the word line DWL. The bit line-side capping layer BCL may include an air gap AG. A bit line-side capping layer BCL having an air gap AG embedded therein may be disposed between the first word line WL1 and the bit line BL, and a bit line-side capping layer BCL having an air gap AG embedded therein may be disposed between the second word line WL2 and the bit line BL. The bit line-side capping layers BCL may vertically overlap the first source/drain region SR.

The air gap AG may be disposed between the bit line BL and the word line DWL. The air gap AG may be disposed above and below the active layer ACT, respectively. The air gap AG may be disposed above and below the first source/drain region SR, respectively. The air gap AG may be parallel to the active layer ACT and the first source/drain region SR. The air gap AG may have a larger critical dimension than either of the active layer ACT and the first source/drain region SR. For example, the width of the air gap AG along the third direction D3 may be greater than the width of the first source/drain region SR along the third direction D3.

The bit line-side capping layer BCL may further include an inner liner L1 and an outer liner L2, and the air gap AG may be closed (or bounded at least partially) by the inner liner L1 and the outer liner L2. That is, the air gap AG may be an embedded air gap disposed between the inner liner L1 and the outer liner L2.

The bit line-side capping layer BCL may have an isolated structure. The bit line-side capping layer BCL having an isolated structure may be disposed to correspond to each of the bit lines BL, but adjacent bit line-side capping layers BCL having an isolated structure may be spaced apart from each other. Accordingly, the air gap AG of the bit line-side capping layer BCL may be spaced apart from each other and correspond to each of the bit lines BL. In contrast to the air gap AG of FIG. 26 having a horizontally-elongated structure along one sidewall of the word line DWL, the air gap AG of FIG. 15 is an isolated structure and adjacent air gaps may not be connected to each other. The air gap AG of FIG. 15 is referred to hereinafter as an ‘isolated air gap’ or an ‘isolated structure’.

In the air gap AG of FIG. 15, the air gap AG may be disposed between the flat surfaces of the word line DWL (see WLF of FIG. 26) and the bit lines BL. The air gap AG may not be disposed between the recess surfaces of the word line DWL (refer to WLR of FIG. 26) and the bit lines BL.

The air gap AG of FIG. 26 may be disposed between the flat surfaces WLF of the word line DWL and the bit lines BL, and also between the recess surfaces WLR of the word line DWL and the bit line BL.

As described above, the bit line-side capping layer BCL may have a structure including an embedded air gap AG closed by the inner liner L1 and the outer liner L2. The volume of the air gap AG in the bit line-side capping layer BCL may be greater than the volume of the inner liner L1 and the outer liner L2.

The inner liner L1 and the outer liner L2 of the bit line-side capping layer BCL may include silicon oxide, silicon carbon oxide, silicon nitride, or a combination thereof.

Vertical isolation layers VIL (as shown in FIG. 15) may be disposed between adjacent bit lines BL in the third direction D3. The vertical isolation layers VIL may include a dielectric material. The vertical isolation layers VIL may extend vertically in the first direction D1.

Referring to FIG. 15, since the air gap AG is formed between the word line DWL and the bit line BL, it is possible to reduce the parasitic capacitance between the word line DWL and the bit line BL, and thus the sensing margin may be reduced.

In another embodiment, the capacitor-side capping layer CC may also include an embedded air gap in the same manner as the bit-line-side capping layer BCL.

The present invention described above is not limited to the above-described embodiments and the accompanying drawings. It will be apparent to those skilled in the art that various changes and modifications can be made within the scope of the technical spirit of the present invention.

What is claimed is:

1. A semiconductor device comprising:
a lower structure;
a plurality of active layers horizontally oriented along a direction parallel to a surface of the lower structure;
a plurality of bit lines coupled to the active layers, respectively, and extended in a vertical direction to the surface of the lower structure;
a word line horizontally extended in a direction crossing the active layers over the active layers; and
a capping layer disposed between the bit lines and the word line, the capping layer including an air gap disposed between the bit lines and the word lines.

2. The semiconductor device of claim 1, wherein the capping layer further includes an inner liner and an outer liner, wherein the air gap is bounded by the inner liner and the outer liner.

3. The semiconductor device of claim 2, wherein at least one of the inner liner and the outer liner includes silicon oxide, silicon carbon oxide, silicon nitride, or a combination thereof.

4. The semiconductor device of claim 1, wherein the word line includes a double word line structure or a single word line structure.

5. The semiconductor device of claim 1, wherein the air gap is extended along a sidewall of the word line.

6. The semiconductor device of claim 1, wherein the air gap includes an isolated structure disposed to correspond to each of the bit lines.

7. A semiconductor device comprising
a lower structure;
a plurality of active layers horizontally spaced apart along a direction parallel to a surface of the lower structure;
a word line horizontally extended in a direction crossing the active layers over the active layers;
a plurality of bit lines coupled to first sides of the active layers, respectively, and extended in a vertical direction to the surface of the lower structure;
a plurality of capacitors coupled to second sides of the active layers, respectively;
a bit line-side capping layer disposed between the bit lines and the word line, the bit line-side capping layer including an air gap disposed between the bit lines and the word line; and
a capacitor-side capping layer disposed between the capacitors and the word line.

8. The semiconductor device of claim 7, wherein the bit line-side capping layer further includes an inner liner and an outer liner, and wherein the air gap is bounded by the inner liner and the outer liner.

9. The semiconductor device of claim 8, wherein at least one of the inner liner and the outer liner includes silicon oxide, silicon carbon oxide, silicon nitride, or a combination thereof.

10. The semiconductor device of claim 7, wherein the capacitor-side capping layer includes silicon oxide, silicon carbon oxide, silicon nitride, or a combination thereof.

11. The semiconductor device of claim 7, wherein at least one of the active layers includes a silicon layer, monocrystalline silicon layer, polysilicon layer, or oxide semiconductor material.

12. The semiconductor device of claim 7, wherein the word line includes a double word line structure or a single word line structure.

13. The semiconductor device of claim 7, wherein the air gap is extended along a sidewall of the word line.

14. The semiconductor device of claim 7, wherein the air gap includes an isolated structure disposed to correspond to each of the bit lines.
